(19) United States
(12) Patent Application Publication
(10) Pub. No.: US 2005/0002165 A1
(43) Pub. Date: Jan. 6, 2005

(54) Laser diode for optical pickup and method of protection

(75) Inventors: Joon-ho Cha, Yongin-si (KR); Song-oul Ahn, Suwon-si (KR)

Correspondence Address: STAAS & HALSEY LLP, SUITE 700, 1201 NEW YORK AVENUE, N.W., WASHINGTON, DC, 20005, US

(73) Assignee: Samsung Electronics Co., LTD, Suwon-city (KR)

(21) Appl. No.: 10/719,021

(22) Filed: Nov. 24, 2003

(30) Foreign Application Priority Data
Nov. 26, 2002 (KR) 2002-74130

(51) Int. Cl. H05K 5/00

(52) U.S. Cl. 361/733

(57) ABSTRACT

A laser diode for an optical pickup. The laser diode includes active connectors and a ground connector protruding so as to be electrically connectable to a laser diode drive integrated circuit. The ground connector is longer than the active connectors, and an end of the ground connector is acutely shaped compared to ends of the active connectors, or both. Accordingly, the laser diode is prevented from malfunction due to electrostatic discharge.

### CROSS-REFERENCE TO RELATED APPLICATIONS

This application claims the benefit of Korean Patent Application No. 2002-74130, filed on Nov. 26, 2002, in the Korean Intellectual Property Office, the disclosure of which is incorporated herein by reference.

### BACKGROUND OF THE INVENTION

1. Field of the Invention

The present invention relates to a laser diode for an optical pickup, and more particularly, to a laser diode for an optical pickup, where the laser diode is protected from damage caused by an electrostatic discharge (ESD).

2. Description of the Related Art

A laser diode is an indispensable optical element in the field of optical devices. Since the laser diode is sensitive to static electricity, the protection of the laser diode is managed by taking measures to prevent electrostatic discharge (ESD) in the manufacturing process. However, it is impossible to completely prevent ESD under many given conditions or environments. Damage to laser diodes due to ESD frequently occurs during manufacture, when combining a laser diode with an optical device, and when using a laser diode in an optical device.

FIG. 1 is a side view of a conventional laser diode for an optical pickup. Referring to FIG. 1, a laser diode 10 includes a laser diode (LD) connector 11, a photodiode (PD) connector 12, and a ground connector 13 which protrude so as to be electrically connectable to a laser diode driving integrated circuit (IC) (not shown) driving the laser diode 10. The LD connector 11 and the PD connector 12 are active connectors. The active connectors 11 and 12, and the ground connector 13 have the same length.

FIG. 5 shows the conventional laser diode 10 mounted on a printed circuit board (PCB) 50 connecting the laser diode 10 to the laser diode driving IC (not shown) with solder joints 60. Portions of the active connectors 11 and 12, and the ground connector 13 protruding through the back of the PCB 50 may be cut to a predetermined length. Regardless of whether the connectors are cut or not cut, the active connectors 11 and 12, and the ground connector 13 have the same length.

### SUMMARY OF THE INVENTION

The present invention provides a laser diode for an optical pickup resistant to damage caused by ESD.

Aspects of the present invention also provide a laser diode for an optical pickup resistant to damage caused by ESD during manufacture of the laser diode, combining the laser diode with an optical device, and when using the laser diode in the optical device.

According to an aspect of the present invention, a laser diode is provided for an optical pickup in which active connectors and a ground connector protrude so as to be electrically connectable to a laser diode driving integrated circuit and the ground connector is longer than the active connectors.

According to another aspect of the present invention, a laser diode is provided for an optical pickup in which active connectors and a ground connector protrude so as to be electrically connectable to a laser diode driving integrated circuit and an end of the ground connector is acutely shaped compared to ends of the active connectors.

According to still another aspect of the present invention, a laser diode is provided for an optical pickup in which active connectors and a ground connector are fixedly insertable into a printed circuit board, connectable to a laser diode driving integrated circuit, so as to be electrically connectable to the laser diode driving integrated circuit and protrude through the back of the printed circuit board. The protruding portion of the ground connector is longer than the protruding portions of the active connectors.

According to yet another aspect of the present invention, a laser diode for an optical pickup is provided in which active connectors and a ground connector are fixedly insertable into a printed circuit board connectable to a laser diode driving integrated circuit so as to be electrically connectable to the laser diode driving integrated circuit and protrude through the back of the printed circuit board and an end of the protruding portion of the ground connector is acutely shaped compared with ends of the protruding portions of the active connectors.

Additional aspects and/or advantages of the invention will be set forth in part in the description which follows and, in part, will be obvious from the description, or may be learned by practice of the invention.

### BRIEF DESCRIPTION OF THE DRAWINGS

The above and/or other aspects and advantages of the invention will become apparent and more readily appreciated from the following description of the embodiments, taken in conjunction with the accompanying drawings of which:

FIG. 1 is a side view of a conventional laser diode for an optical pickup;

FIG. 2 is a side view of a laser diode for an optical pickup according to an embodiment of the present invention;

FIG. 3 is a side view of a laser diode for an optical pickup according to another embodiment of the present invention;

FIG. 4 is a side view of a laser diode for an optical pickup according to still another embodiment of the present invention;

FIG. 5 shows the conventional laser diode mounted on a PCB; and

FIG. 6 shows an aspect of the present invention laser diode mounted on a PCB.

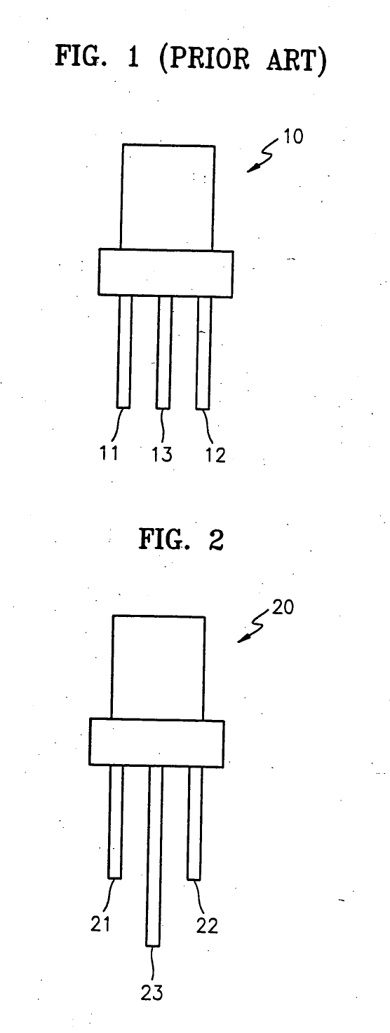

### DETAILED DESCRIPTION OF THE INVENTION

Reference will now be made in detail to the embodiments of the present invention examples of which are illustrated in the accompanying drawings, wherein like reference numerals refer to the like elements throughout. The embodiments are described below to explain the present invention by referring to the figures.

FIG. 2 is a side view of a laser diode for an optical pickup according to an aspect of the present invention. Referring to FIG. 2, a laser diode 20 has active connectors 21 and 22 and a ground connector 23 all protruding so as to be electrically connectable to a laser diode driving IC (not shown). In the laser diode 20 according to an aspect of the present invention, the ground connector 23 is longer than the active connectors 21 and 22. Thus, static electricity generated around the, laser diode 20 is transmitted to the ground connector 23 due to the longer length of the ground connector 23. When a high voltage due to static electricity is applied to the ground connector 23 current flows through the ground connector 23. Thus, a probability of damage to the laser diode 20 is lower than when the current flows through the active connectors 21 and 22. Accordingly, the above-described structure can protect the laser diode 20 from being damaged by ESD.

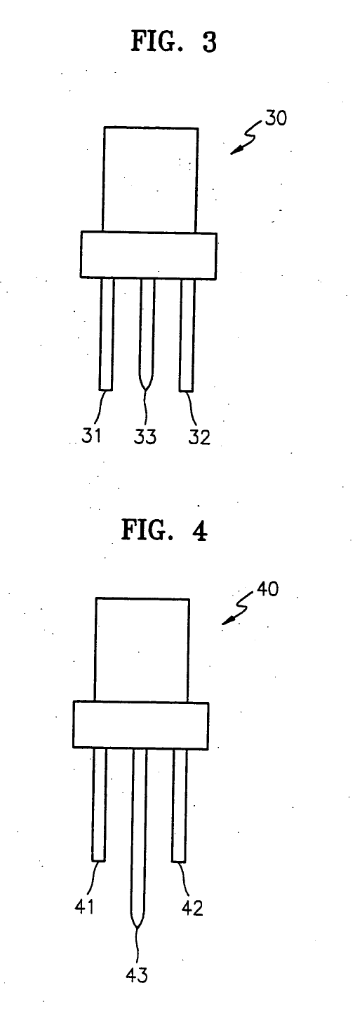

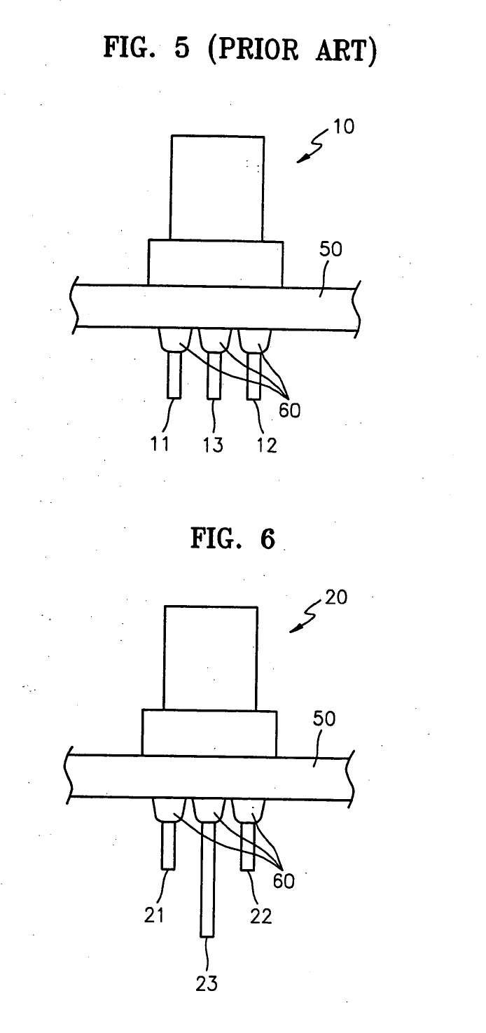

FIG. 3 is a side view of a laser diode for an optical pickup according to another aspect of the present invention. Referring to FIG. 3, a laser diode 30 includes active connectors 31 and 32 and a ground connector 33 all projecting so as to be electrically connectable to a laser diode driving IC (not shown). In addition, the laser diode 30 is characterized in that an end of the ground connector 33 is acutely shaped compared to the ends of active connectors 31 and 32.

A charge is more apt to concentrate around a portion having a smaller radius of curvature, i.e., an acutely shaped portion, and charge density at the acutely shaped portion is higher than at other portions. When static electricity is generated in the vicinity of the connectors of the laser diode 30, a charge having an opposite polarity to the charge of the static electricity forms around the active connectors 31 and 32 and the ground connector 33. Since the end of the ground connector 33 is acutely shaped compared to the ends of the active connectors 31 and 32, the charge density at the end of the ground connector 33 is the highest. As a result, air insulation breakdown occurs near the end of the ground connector 33 resulting in the flow of the static electricity toward the ground connector 33. Accordingly, voltage caused by static electricity is applied to the ground connector 33 and a current flows through the ground connector 33. Thus, the probability for the laser diode 30 to malfunction is lower than if the current flowed through the active connectors 31 and 32. Consequently, the above-described structure prevents the laser diode from a malfunction due to ESD.

FIG. 4 is a side view of a laser diode for an optical pickup according to another aspect of the present invention. Referring to FIG. 4, a ground connector 43, and active connectors 41 and 42 protrude from a laser diode 40. The ground connector 43 is longer than the active connectors 41 and 42. In addition, an end of the ground connector 43 is acutely shaped compared to either of the ends of the active connectors 41 and 42.

This aspect of the invention attains both of the effects of the aspects of the invention described with reference to FIGS. 2 and 3. Therefore, static electricity generated in the vicinity of the active connectors 41 and 42 and the ground connector 43 of the laser diode 40 is more likely to flow toward the ground connector 43 and not toward either of the active connectors 41 and 42. When static electricity causes a voltage to be applied to the ground connector 43 so that a current flows through the ground connector 43, the possibility for the laser diode 40 to malfunction is lower than if the current flowed through the active connectors 41 and 42. Accordingly, the above-described structure protects the laser diode 40 from malfunctioning due to ESD.

The aspects of the invention described with reference to FIGS. 2 through 4 are useful to prevent a laser diode from being damaged by ESD when manufacturing the laser diode, when distributing the laser diode, when combining the laser diode with an optical device, and when using the laser diode in an optical device.

FIG. 6 shows the laser diode 20 mounted on a PCB 50 connected to a laser diode driving IC (not shown) and fixed by solder joints 60. Portions of the active connectors 21 and 22, and the ground connector 23 projecting through the back of the PCB 50 may be cut. Regardless of any cutting, the projecting portion of the ground connector 23 is longer than the projecting portions of the active connectors 21 and 23. Static electricity generated around the laser diode 20 is localized at the ground connector 23 due to its longer projecting portion. Upon a discharge of voltage due to the static electricity, the discharge is applied to the ground connector 23, and a current flows through the ground connector 23. Thus, the possibility for the laser diode 20 to malfunction is lower than if the current flowed through the active connectors 21 and 22. Accordingly, the above-described structure prevents the laser diode 20 from malfunction due to ESD when the laser diode 20 is used in an optical device after being installed in the optical device.

Though it is not shown, an end of a portion of a ground connector protruding through the back of the PCB 50 may be acutely shaped compared to the end portions of the active connectors 21 and 22 protruding through the back of the PCB 50. To be more specific, a laser diode having the same structure as the laser diode 30 shown in FIG. 3 is mounted on the PCB 50 and then fixed by the solder joints 60.

Alternatively, a laser diode having a different structure than the laser diode 30 shown in FIG. 3 may be mounted on the PCB 50, and then, a ground connector among the connectors of the laser diode, is actutely shaped.

Since an end of the ground connector is acutely shaped compared to the ends of active connectors, charge density is the highest at the end of the ground connector. Thus, air insulation breakdown occurs around the end of the ground connector allowing static electricity to flow toward the ground connector. As a result, static electricity applies a voltage to the ground connector, and a current flows through the ground connector. Thus, the possibility for the laser diode to malfunction is lower than if the current flowed through the active connectors. Consequently, the above-described structure prevents the laser diode from malfunction due to ESD, when the laser diode is used in an optical device after being installed in the optical device.

Though it is not shown, according to another aspect of the present invention, a portion of a ground connector protruding through a back of the PCB is longer than portions of active connectors. In addition, the end of the ground connector is also acutely shaped compared to the ends of the active connectors. To be more specific, a laser diode having the same structure as the laser diode 40 shown in FIG. 4 is mounted on the PCB 50 and then fixed by the solder joints 60. Alternatively, a laser diode having a different structure from the laser diode 40 shown in FIG. 4 may be mounted on the PCB 50, and the connectors cut so that the ground connector is the longest and most acutely shaped of the connectors of the laser diode.

This aspect of the present invention achieves both of the effects as previously described. Therefore, static electricity generated around the laser diode, will flow toward the ground connector and not toward either of the active connectors. Upon discharge of the static electricity a voltage is applied to the ground connector and a current flows through the ground connector. Thus, the possibility for the laser diode to malfunction is lower than if the current flowed through the active connectors. Accordingly, the above-described structure protects the laser diode from malfunction due to ESD when the laser diode is actually used in an optical device after being installed in the optical device.

As described above, according to aspects of the present invention, a laser diode for an optical pickup is protected from malfunction when manufacturing the laser diode, when distributing the laser diode, when combining the laser diode with an optical device, and when using the laser diode in the optical device due to ESD. As a result, costs are reduced and reliable operation of the optical device accomplished.

Although a few embodiments of the present invention have been shown and described, it would be appreciated by those skilled in the art that changes may be made in this embodiment without departing from the principles and spirit of the present invention, the scope of which is defined in the claims and their equivalents.

1. A laser diode for an optical pickup, comprising:
at least one active connector; and
a ground connector,
wherein the at least one active connector and the ground connector protrude from the laser diode so as to be electrically connectable to a laser diode driving integrated circuit and the ground connector is longer than the at least one active connector.

2. The laser diode according to claim 1, wherein the end of the ground connector is acutely shaped compared to the end of the least one active connector.

3. The laser diode according to claim 1, the at least one active connector comprising:
a first connector, and
a second connector.

4. The laser diode according to claim 3, wherein the first connector is a laser diode connector and the second connector is a photodiode connector.

5. A laser diode for an optical pickup, comprising:
at least one active connector, and
a ground connector,
wherein the at least one active connector and the ground connector protrude so as to be electrically connectable to a laser diode driving integrated circuit an end of the ground connector is acutely shaped compared to an end of the at least one active connector.

6. A laser diode for a printed circuit board connectable to a laser diode driving device of an integrated circuit of an optical pickup, comprising:
at least one active connector fixedly insertable into the printed circuit board; and
a ground connector fixedly insertable into the printed circuit board, wherein the inserted at least one active connector and the ground connector are electrically connectable to the laser diode driving integrated circuit protruding through the back of the printed circuit board and a protruding portion of the ground connector is longer than a protruding portion of the at one least active connector.

7. The laser diode according to claim 6, wherein the inserted at least one active connector and the ground connector are fixed to the printed circuit board by solder joints.

8. The laser diode according to claim 6, wherein an end of the protruding portion of the ground connector is acutely shaped compared to an end of the protruding portion of the at least one active connector.

9. The laser diode according to claim 6, the at least one active connector comprising:
a first connector, and
a second connector.

10. The laser diode according to claim 9, wherein the first connector is a laser diode connector and the second connector is a photodiode connector.

11. A laser diode a printed circuit board connectable to a laser diode driving device of an integrated circuit of an optical pickup, comprising:
at least one active connector fixedly insertable into the printed circuit board, and
a ground connector fixedly insertable into the printed circuit board,
wherein the inserted at least one active connector and the ground connector are electrically connectable to the laser diode driving integrated circuit protruding through the back of the printed circuit board, and an end of the protruding portion of the ground connector is acutely shaped compared with an end of the protruding portion of the at least one active connector.

12. The laser diode according to claim 11, wherein the inserted at least one active connector and the ground connector are fixed to the printed circuit board by solder joints.

13. The laser diode according to claim 12, the at least one active connector comprising:
a first connector, and
a second connector.

14. The laser diode according to claim 13, wherein the first connector is a laser diode connector and the second connector is a photodiode connector.

15. A laser diode for an optical pickup, comprising:
at least one active connector; and
a ground connector longer than the at least one active connector and more acutely shaped than an end of the at least one active connector.

16. The laser diode according to claim 15, the at least one active connector comprising:
a first connector, and
a second connector.

17. The laser diode according to claim 16, wherein the first connector is a laser diode connector and the second connector is a photodiode connector.

18. A printed circuit board system connectable to a laser diode driving integrated circuit of an optical pickup, comprising:
a printed circuit board; and
a laser diode having at least one active connector and a ground connector, the connectors insertable into the printed circuit board,
wherein the inserted at least one active connector and the ground connector protrude from the laser diode so as to be electrically connectable to the laser diode driving integrated circuit and the ground connector is at least longer than the at least one active connector and more actutely shaped than the at least one active connector.

19. The printed circuit board system according to claim 18, wherein the inserted at least one active connector and the ground connector are fixed to the printed circuit board by solder joints.

20. The printed circuit board system according to claim 18, the at least one active connector comprising:
a first connector, and
a second connector.

21. The printed circuit board system according to claim 20, wherein the first connector is a laser diode connector and the second connector is a photodiode connector.

22. A laser diode driving integrated circuit system for an optical pickup, comprising:
a laser diode driving integrated circuit;
a printed circuit board connectable to the laser diode driving integrated circuit; and
a laser diode having at least one active connector and a ground connector, the connectors insertable into the printed circuit board,
wherein the inserted at least one active connector and the ground connector protrude from the laser diode so as to be electrically connectable to the laser diode driving integrated circuit and the ground connector is longer than at least one active connector and more actutely shaped than the at least one active connector.

23. The laser diode driving integrated circuit system according to claim 22, wherein the inserted at least one active connector and the ground connector are fixed to the printed circuit board by solder joints.

24. The laser diode driving integrated circuit system according to claim 22, the at least one active connector comprising:
a first connector, and
a second connector.

25. The laser diode driving integrated circuit system according to claim 24, wherein the first connector is a laser diode connector and the second connector is a photodiode connector.

26. A method of reducing malfunctions due to electrostatic discharge of a laser diode insertable into a printed circuit board that is connectable to a laser diode driving integrated circuit of an optical pickup, comprising:
inserting the laser diode into the printed circuit board so that active connectors and a ground connector protrude through the printed circuit board; and
at least one of cutting the active connectors and the ground connector so that the active connectors are shorter in length then the ground connector and cutting the end of the ground connector so that the ground connector is more acutely shaped than the active connectors.

27. The method according to claim 26, further comprising soldering the connectors to the printed circuit board.

28. The method according to claim 26, wherein the inserted at least one active connector and the ground connector are fixed to the printed circuit board by solder joints.

29. The method according to claim 28, the at least one active connector comprising:
a first connector, and
a second connector.

30. The method according to claim 29, wherein the first connector is a laser diode connector and the second connector is a photodiode connector.
